(19) United States
(12) Patent Application Publication
(10) Pub. No.: US 2026/0033180 A1
(43) Pub. Date: Jan. 29, 2026

(54) DISPLAY PANEL AND DISPLAY DEVICE

(71) Applicants: Yunnan Invensight Optoelectronics Technology Co., Ltd., Kunming, Yunnan (CN); BOE TECHNOLOGY GROUP CO., LTD., Beijing (CN)

(72) Inventors: Chao PU, Beijing (CN); Shengji YANG, Beijing (CN); Junyan YANG, Beijing (CN); Xiaochuan CHEN, Beijing (CN); Kuanta HUANG, Beijing (CN); Pengcheng LU, Beijing (CN); Yuhao LEE, Beijing (CN); Hongtao YU, Beijing (CN); Zhao MA, Beijing (CN); Mingrui ZHANG, Beijing (CN); Liuzeming QU, Beijing (CN); Zhuoyang XIE, Beijing (CN); Qi SU, Beijing (CN)

(73) Assignees: Yunnan Invensight Optoelectronics Technology Co., Ltd., Kunming, Yunnan (CN); BOE TECHNOLOGY GROUP CO., LTD., Beijing (CN)

(21) Appl. No.: 18/996,210

(22) PCT Filed: Nov. 30, 2022
(86) PCT No.: PCT/CN2022/135379

§ 371 Date: Jan. 17, 2025

(51) Int. Cl. H10K 59/131; H10H 29/49

(52) U.S. Cl. CPC H10K 59/131; H10H 29/49

(57) ABSTRACT

The present disclosure provides a display panel (PNL) and a display device. The display panel (PNL) comprises a display area (AA) and a binding area (BB) located on one side of the display area (AA); wherein, in the binding area (BB), there are multiple pads (PAD) arranged in sequence along a first direction DH; wherein, the multiple pads (PAD) comprise at least multiple first pads (PA) and multiple second pads (PB); each of the first pads (PA) comprises a first connection portion (PAY) and a first structure (PAX) located on one side of the first connection portion (PAY) near the display area (AA), a maximum width of the first structure (PAX) is greater than that of the first connection portion (PAY). The first structure (PAX) is located on one side of the second pad (PB) near the display area (AA).

### CROSS-REFERENCE TO RELATED APPLICATIONS

This application is a National Stage application of PCT/CN2022/135379, filed on Nov. 30, 2022, which is incorporated herein by reference in their entirety for all purposes.

### TECHNICAL FIELD

The present disclosure relates to the art of display technology, specifically to a display panel and a display device.

### BACKGROUND

In existing display panels, the pads are rectangular and arranged in a row with equal spacing. However, with the increase of resolution, more and more power lines, signal lines, and control lines are required for display panels, and the number of required pads is also increasing. This has resulted in the pads no longer being able to fully meet the requirements for electrical connections.

It should be noted that the information disclosed in the background is only for enhancing the understanding of the background of the present disclosure, and therefore may include information that does not constitute prior art known to those skilled in the art.

### SUMMARY

The purpose of the present disclosure is to overcome the shortcomings of the prior art and provide a display panel and display device that improve the compatibility of the display panel with different binding processes.

According to one aspect of the present disclosure, a display panel is provided, wherein the display panel comprises a display area and a binding area located on one side of the display area; wherein, in the binding area, there are multiple pads arranged in sequence along a first direction;

wherein, the multiple pads at least include multiple first pads and multiple second pads; each of the first pads comprises a first structure and a first connection portion located on one side of the first structure away from the display area, a maximum width of the first structure is greater than a maximum width of the first connection portion;

the first structure is located on one side of a corresponding second pad near the display area.

According to one embodiment of the present disclosure, each of the second pads comprises a second connection portion and a second structure located on one side of the second connection portion near the display area, and a maximum width of the second structure is greater than a maximum width of the second connection portion.

According to one embodiment of the present disclosure, the first connection portion comprises a first sub connection portion electrically connected to the first structure and a second sub connection portion located on one side of the first sub connection portion away from the first structure;

a width of the first sub connection portion is less than or equal to a width of the second sub connection portion.

According to one embodiment of the present disclosure, the first sub connection portion is located between adjacent second structures; the second sub connection portion is located between adjacent second connection portions.

According to one embodiment of the present disclosure, the width of the second sub connection portion is 0.8 to 1.2 times a width of the second connection portion.

According to one embodiment of the present disclosure, a third transition structure is included between the first sub connection portion and the second sub connection portion; the third transition structure is respectively connected to the first sub connection portion and the second sub connection portion; a width of the third transition structure gradually increases along a direction away from the display area.

According to one embodiment of the present disclosure, a shape of the first structure comprises at least one of a right angled polygon and a rounded polygon;

the first structure includes a first transition structure connected to the first connection portion, and a first main body structure located on a side of the first transition structure away from the first connection portion;

a width of the first transition structure gradually decreases along a direction away from the display area.

According to one embodiment of the present disclosure, the shape of the second structure comprises at least one of a right angled polygon and a rounded polygon;

the second structure comprises a second main body structure and a protruding structure located on one side of the second main body structure near the display area; at least a portion of an edge of the protruding structure is parallel to an edge of an adjacent one of the first structures.

According to one embodiment of the present disclosure, the protruding structure is trapezoidal;

a width of the protruding structure gradually decreases along a direction near the display area; the side of the protruding structure is parallel to a side of an adjacent one of the first transition structures.

According to one embodiment of the present disclosure, a shape of the second structure comprises at least one of a right angled polygon and a rounded polygon;

the second structure has a second main body structure and a second transition structure located on one side of the second main body structure away from the display area;

one end of the second transition structure is connected to the second connection portion, and the other end is connected to the second main body structure; a size of the second transition structure gradually decreases in the direction away from the display area.

According to one embodiment of the present disclosure, a width of the first structure is 0.8 to 1.2 times a width of the second structure.

According to one embodiment of the present disclosure, the first structures are arranged in a row along the first direction; the second structures are arranged in another row along the first direction.

According to one embodiment of the present disclosure, a width of a gap between the first sub connection portion and the second structure is smaller than a width of a gap between the second sub connection portion and the second connection portion.

According to one embodiment of the present disclosure, the first connection portion is located on one side of a corresponding first pad along the first direction, and one first pad and the second pad form a pad group;

in a same pad group, the second pad is located in a gap defined by the first structure and the first connection portion; the second pad does not protrude from the first structure along the first direction.

According to one embodiment of the present disclosure, the first pads are arranged axially symmetrically; an extension line of a symmetry axis of the first pad is located in a gap between two adjacent second pads;

and/or, the second pads are arranged axially symmetrically; an extension line of a symmetry axis of the second pads is located in a gap between two adjacent first structures.

According to one embodiment of the present disclosure, in at least a portion of the binding area, the first pads and the second pads are alternately arranged in sequence along the first direction.

According to one embodiment of the present disclosure, the first connection portion passes through the gap between adjacent second pads.

According to one embodiment of the present disclosure, the multiple pads include third pads, the multiple first pads and the multiple second pads form a first pad area, and the third pads are respectively located on both sides of the first pad area;

wherein, each of the third pads comprises a third structure and a third connection portion, and a width of the third structure is greater than or equal to a width of the third connection portion along a direction facing the first pad area.

According to one embodiment of the present disclosure, at least one top corner of each of the pads is an arc-shaped corner.

According to one embodiment of the present disclosure, the maximum width of the first structure and a maximum width of the second pad are both not less than 200 microns.

According to another aspect of the present disclosure, a display device comprising the display panel is provided.

It should be understood that the above general description and the subsequent detailed description are only exemplary and explanatory, and cannot limit the present disclosure.

### BRIEF DESCRIPTION OF THE DRAWINGS

The accompanying drawings are incorporated into the specification and form a part of the specification, illustrating embodiments in accordance with the present disclosure and used together with the specification to explain the principles of the present disclosure. It is obvious that the drawings described below are only some embodiments of the present disclosure. For those skilled in the art, other drawings can be obtained based on these drawings without creative work.

FIG. 1 is a schematic view of a structure of a display panel in one embodiment of the present disclosure.

FIG. 2 is a schematic view of a structure of a display module in a first embodiment of the present disclosure.

FIG. 3 is a schematic view of a partial cross-sectional structure of the display module in the first embodiment of the present disclosure.

FIG. 4 is a schematic view of the structure of the display module in a second embodiment of the present disclosure.

FIG. 5 is a schematic view of a partial cross-sectional structure of the display module in the second embodiment of the present disclosure.

FIG. 6 is a schematic view of a structure of some adjacent pads in a binding area in one embodiment of the present disclosure.

FIG. 7 is a partially enlarged schematic view of FIG. 6.

FIG. 8 is a schematic view of the structure of some adjacent pads in the binding area in one embodiment of the present disclosure.

FIG. 9 is a schematic view of the structure of some adjacent pads in the binding area in one embodiment of the present disclosure.

FIG. 10 is a schematic view of the structure of some adjacent pads in the binding area in one embodiment of the present disclosure.

FIG. 11 is a schematic view of the structure of some adjacent pads in the binding area in one embodiment of the present disclosure.

FIG. 12 is a schematic view of the structure of some adjacent pads in the binding area in one embodiment of the present disclosure.

FIG. 13 is a schematic view of the structure of some adjacent pads in the binding area in one embodiment of the present disclosure.

FIG. 14 is a schematic view of the structure of some adjacent pads in the binding area in one embodiment of the present disclosure.

FIG. 15 is a schematic view of the structure of some adjacent pads in the binding area in one embodiment of the present disclosure.

### DETAILED DESCRIPTION

The example embodiments will now be described more comprehensively with reference to the accompanying drawings. However, the example embodiments can be implemented in various forms and should not be understood as limited to the embodiments described herein; on the contrary, the embodiments provided herein make the present disclosure comprehensive and complete, and fully convey the concept of example embodiments to those skilled in the art. The same reference numbers in the drawings indicate the same or similar structures, therefore their detailed descriptions will be omitted. In addition, the accompanying drawings are only illustrative of the present disclosure and are not necessarily drawn to scale.

The terms “one”, “a”, “this”, “said”, and “at least one” are used to indicate the existence of one or more elements/components/etc; the terms “including” and “having” are used to indicate open-ended inclusion and refer to the possibility of additional elements/components/etc. in addition to the listed ones; the terms “first”, “second”, “third”, etc. are only used as markers and not to limit the number of their objects.

In the prior art, the pads on a display panel are arranged in a row and arranged in a rectangular shape. In high-resolution display products, such as in 2K or higher silicon-based display panels (for example, display panels with resolutions of 2K, 2.5K, 3K, 4K, or 8K), the display panel requires more pads to input power signals, data signals, and control signals. However, this will result in a decrease in widths of the pads, which in turn leads to an increase in impedance when binding the flexible circuit board with anisotropic conductive adhesive; even this may result in the pad being unable to undergo a wire bonding process, leading to the display panel being incompatible with the wire bonding process.

The embodiments of the present disclosure provide a display panel that may be compatible with the wire bonding and conductive adhesive binding processes through the irregular design of the pads in case of setting a row of pads, overcoming the impact of increased resolution on wire bonding process.

Referring to FIG. 1, the display panel PNL provided in the present disclosure includes a display area AA and a binding area BB located on one side of the display area AA. Wherein, in the binding area BB, there are multiple pads PAD arranged in sequence along a first direction DH. In the embodiments of the present disclosure, referring to FIGS. 6 to 15, the pads PAD located in the binding area BB at least include multiple first pads PA and multiple second pads PB. Each of the first pads PA includes a first connection portion PAY and a first structure PAX located on a side of the first connection portion PAY near the display area AA, a maximum width of the first structure PAX is greater than a maximum width of the first connection portion PAY. The first structure PAX is located on one side of a second pad PB near the display area AA. In further embodiments, the first connection portion PAY passes through a gap between adjacent second pads PB.

In the display panel PNL provided in the present disclosed embodiment, the first pad PA is provided with a first structure PAX on a side of the second pad PB near the display area AA. On the one hand, the first structure PAX does not need to avoid the second pad PB and may have a larger size, making it suitable for the wire bonding process. On the other hand, the first connection portion PAY does not need to be used for wire bonding and may have a smaller width, which may reduce squeezing of a wiring space of the second pad PB by the first connection portion PAY, allowing the second pad PB having a larger width, thereby enabling the second pad PB to be used for the wire bonding process. Therefore, the display panel PNL disclosed in the present embodiment may ensure that the first structure PAX and the second pad PB are suitable for the wire bonding process. When the conductive adhesive binding process is used to bind a circuit board (such as a flexible circuit board), the anisotropic conductive adhesive may completely cover the first pads PA and the second pads PB, thereby ensuring a larger effective binding area between the circuit board and a corresponding pad PAD, avoiding impedance increase caused by a smaller binding area.

Therefore, the display panel PNL of the present disclosed embodiment is only provided with one row of pads PAD. By designing at least some pads PAD with irregular shapes, the space competition between adjacent pads PAD may be reduced and each pad PAD may have a larger width (maximum width), ensuring that the display panel PNL may be electrically connected to a driving component (such as a driver circuit board) using the wire bonding process or conductive adhesive binding process as needed. This ensures compatibility of the display panel PNL with different binding processes in subsequent applications, thereby improving the versatility of the display panel PNL and achieving purposes of flexible application, wide applicability, and low single-piece cost.

The present disclosed embodiment further provides a display device using the display panel PNL. The display device may be an augmented reality display product such as a VR glass, an AR helmet, or other types of near-eye display products. Due to its compatibility of the wire bonding process and conductive adhesive binding process through a row of pads PAD, the display panel PNL of the display device can overcome or eliminate limitation of an insufficient size of the pads PAD on the high resolution of the display panel PNL. Therefore, the display panel PNL can achieve high-resolution display, such as 2K display or above, or display with 4000 PPI (Pixels Per Inch) or above; this is beneficial for improving the display effect of the display device and enhancing the user experience. Furthermore, the display panel is a silicon-based display panel.

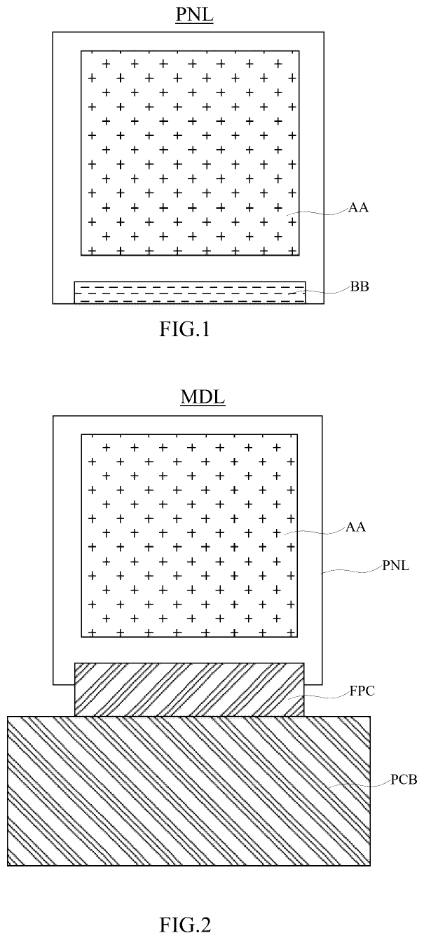

In one embodiment of the present disclosure, referring to FIGS. 2-4, the display device comprises a display module MDL for display, the display module MDL may include the display panel PNL and a driver circuit board PCB electrically connected to the display panel PNL. In this disclosed embodiment, the display panel PNL may be electrically connected to the driver circuit board PCB through a flexible circuit board FPC (the conductive adhesive binding process), or to the driver circuit board PCB through a metal wire WP (the wire bonding process), or through other means.

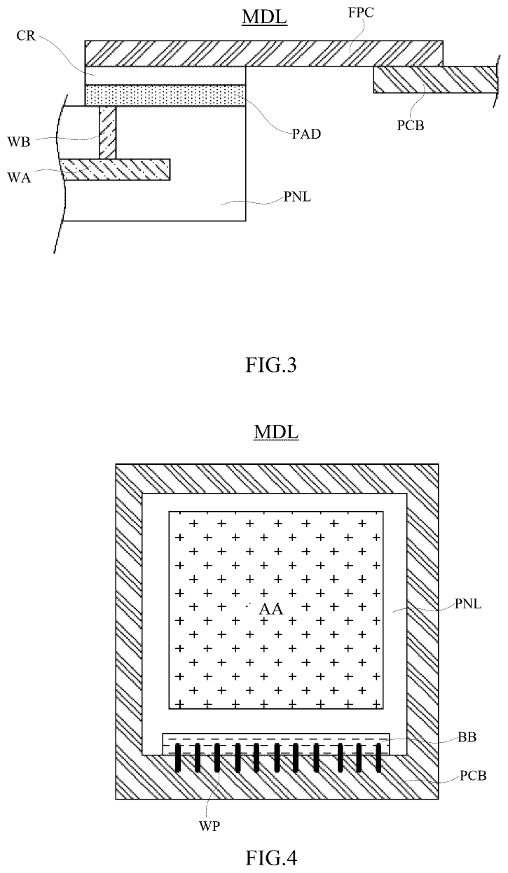

In one example, referring to FIGS. 2 and 3, the display panel PNL in the display module MDL is electrically connected to the driver circuit board PCB using the conductive adhesive binding process. In this example, the display panel PNL is electrically connected to the driver circuit board PCB through the flexible circuit board FPC; wherein, one end of the flexible circuit board FPC is electrically connected to each pad PAD through anisotropic conductive adhesive CR, and the other end is electrically connected to the driver circuit board PCB, such as bonding or plugging. Furthermore, if necessary, the flexible circuit board FPC may be bent to position the driver circuit board PCB on the back of the display panel PNL.

It can be understood that the above-mentioned flexible circuit board FPC is bound to the display panel PNL through anisotropic conductive adhesive, which is only an example of the conductive adhesive binding process used for the display panel PNL; in other examples, the display panel PNL may be electrically connected to a Chip On Film (COP), a circuit board, etc. using anisotropic conductive adhesive.

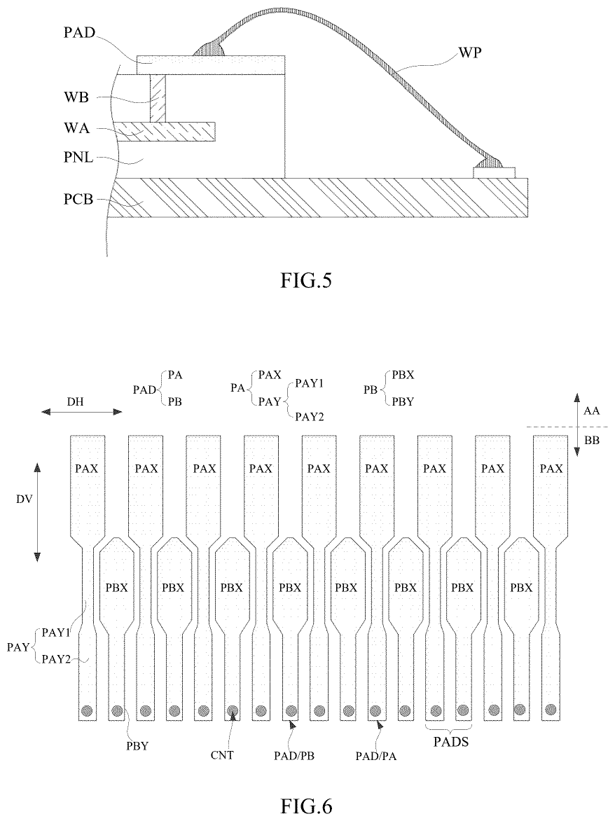

In another example, referring to FIGS. 4 and 5, the display panel PNL in the display module MDL is electrically connected to the driver circuit board PCB using the wire bonding process. The display panel PNL is electrically connected to the driver circuit board PCB through the metal wire WP. One end of the metal wire WP is bound to the pad PAD, and the other end of the metal wire WP may be electrically connected to the driver circuit board PCB, for example, bound to a binding pad on the driver circuit board PCB.

In some embodiments of the present disclosure, the display panel PNL comprises a driving backplane and a pixel layer which are sequentially stacked; wherein, the driving backplane is equipped with a driving circuit layer and a wiring metal layer located between the driving circuit layer and the pixel layer. The driving circuit layer is electrically connected to the wiring metal layer through a metalized via WB (such as a tungsten hole); the wiring metal layer WA is electrically connected to the pad PAD and the pixel layer through the metalized via WB (such as the tungsten hole). It can be understood that the wiring metal layer WA may be one layer or multiple layers that are electrically connected to each other.

Referring to FIGS. 3 and 5, the pad PAD is electrically connected to the wiring metal layer WA through the metalized via WB. In the example of FIG. 6, CNT illustrates an orthographic projection position of the metalized via WB on the display panel PNL. It can be understood that multiple metalized vias WB arranged in an array may be used for electrical connection between the pad PAD and the wiring metal layer WA, in order to reduce connection impedance and improve connection stability. Referring to FIG. 6, the metalized via WB is electrically connected to an outer end of the pad PAD (an end away from the display area AA); in other words, an orthographic projection of the metalized via WB on the display panel PNL overlaps with an outer end of the orthographic projection of the pad PAD on the display panel PNL (the end away from the display area AA). Of course, it can be understood that, as needed, at least some of connection positions between the pad PAD and the metalized via WB may not be at the end of the pad PAD, for example, they may also be located in the middle of the pad PAD, or multiple metalized vias WB distributed in an array may be distributed throughout entire area of the pad.

In the display panel PNL provided in this embodiment of the present disclosure, the pixel layer is equipped with array distributed light-emitting elements as sub pixels of the display panel PNL. Alternatively, the light-emitting elements may be organic light-emitting diodes (OLED), inorganic light-emitting diodes (LED), quantum dot light-emitting diodes (QLED), or other types of current driven light-emitting elements. Of course, in some examples, the light-emitting elements may further be composite light-emitting elements, such as a stacked structure of current driven light-emitting elements and photoluminescent elements. In one example, the light-emitting elements of the display panel PNL are OLEDs.

In some embodiments of the present disclosure, a size of the light-emitting elements of the pixel layer in the first direction DH does not exceed 20 microns, so that the display panel PNL has a high PPI. Furthermore, the size of the light-emitting elements in the first direction DH does not exceed 5 microns, such as between 2.5 and 5 microns, in order to achieve a very high PPI for the display panel PNL, thereby eliminating the graininess of image and improving the delicacy of image, thereby enhancing a near-eye display effect. In the display panel PNL of this embodiment of the present disclosure, at such a high PPI, the irregular design of the pad PAD allows a row of pads PAD to still meet size requirements for binding.

In one embodiment of the present disclosure, a gap between adjacent pixels may not exceed 2 microns, for example, it may be between 0.5 and 1.5 microns. For example, the gap between adjacent pixels is 0.8 microns. This also helps to improve the PPI of the display panel PNL.

Structures, principles, and effects of the pads disclosed in the embodiments of the present disclosure will be further explained and illustrated in conjunction with the accompanying drawings.

In the binding area BB, there are multiple pads PAD arranged in sequence along the first direction DH. In the embodiments of the present disclosure, for the convenience of expression, an arrangement direction of the pads PAD in the binding area BB may be taken as the first direction DH, and a direction parallel to a plane where the display panel PNL is located and perpendicular to the first direction DH may be taken as the second direction DV of the display panel PNL. Furthermore, the binding area BB is located near one edge of the display panel PNL, and the first direction DH is parallel to an extension direction of that edge.

Referring to FIGS. 6-15, the multiple pads PAD include at least multiple first pads PA and multiple second pads PB. Each of the first pads PA includes a first connection portion PAY and a first structure PAX located on the side of the first connection portion PAY near the display area AA. The maximum width L1 of the first structure PAX is greater than widths L2/L3 of the first connection portion PAY. The first structure PAX is located on one side of the second pad PB near the display area AA, and the first connection portion PAY passes through the gap between adjacent second pads PB.

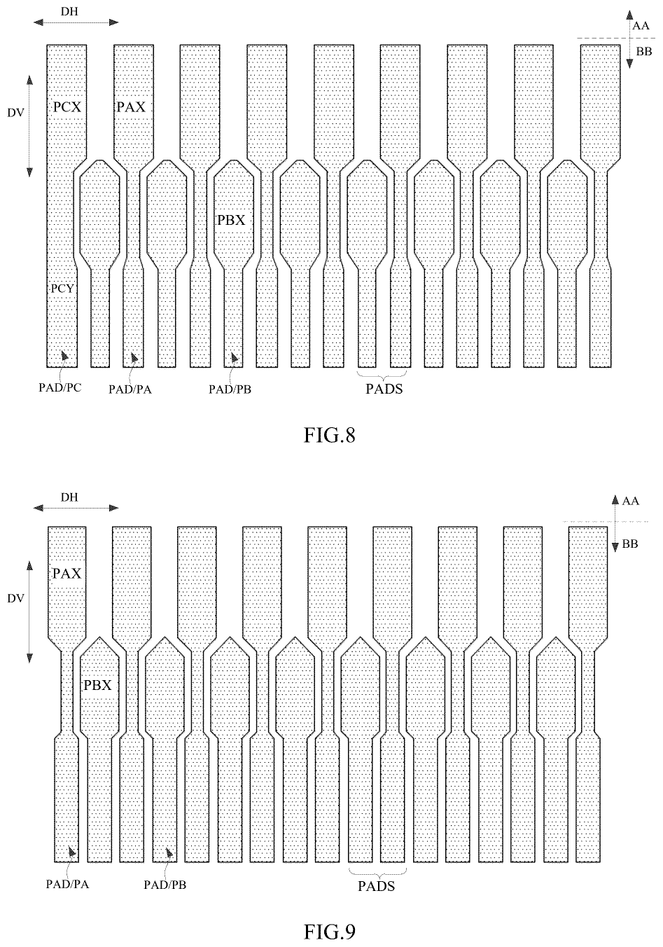

In other words, in the embodiments of the present disclosure, the binding area BB includes at least two different types of pads PAD, namely the first pads PA and the second pads PB. Wherein, at least one type of pads PAD is irregular (non-rectangular) designed, that is, the first pads PA are at least irregular designed. It can be understood that the binding area BB may further include other types of pads PAD, for example, in FIG. 8, the binding area BB further has a third pad PC located at an end of the row of the pads PAD. It can be understood that the second pads PB in the binding area BB may be designed without an irregular shape (for example, the second pads PB in FIG. 13 remains rectangular), or it may be designed with an irregular shape (for example, the second pads PB in FIG. 6 has been designed with an irregular shape). It can also be understood that when both types of pads PAD are designed with irregular shapes, their shapes may be the same or different. For example, in FIG. 6, both the first pads PA and the second pads PB are designed with irregular shapes, and a shape of the first pads PA is different from that of the second pads PB. For example, in FIG. 11, each first pad PA is designed with an irregular shape, and the shapes of adjacent first pads PA are different.

Referring to FIGS. 6-15, the pad PAD includes at least a wire bonding portion with a width of not less than 200 microns, so that the pad PAD can meet the requirements of the wire bonding process for pad PAD width. In the embodiment of the present disclosure, when describing a width of a structure or a gap, it refers to a size of the structure or the gap in the first direction DH. For example, the first structure PAX may serve as the wire bonding portion of the first pad PA, and its maximum width may be no less than 200 microns. For example, in FIG. 6, the second pad PB has a second structure PBX and a second connection portion PBY, with the width of the second structure PBX being greater than that of the second connection portion PBY; the second structure PBX may be used as the wire bonding portion of the second pad PB, and its maximum width may be no less than 200 microns. For example, in FIG. 13, the second pad PB is rectangular without any irregular design, the maximum width of the second pad PB should not be less than 200 microns, and it may be used as the wire bonding portion as a whole. Alternatively, a width of the wire bonding portion of the pad PAD may range from 210 to 250 microns. In this way, it can not only make the wire bonding portion has a larger width to meet the size requirements of the wire bonding, but also avoid the width of the binding area BB being too large due to the wire bonding portion being too wide, which is conducive to reducing the size of the display panel PNL.

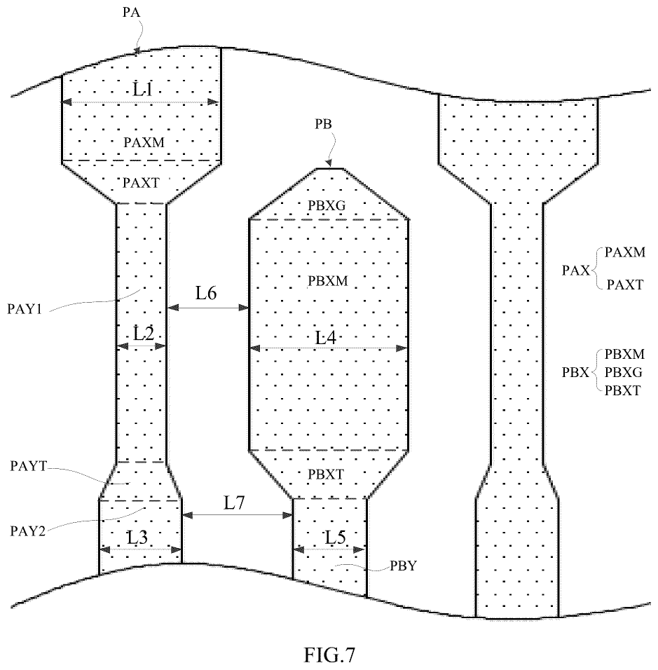

In one embodiment of the present disclosure, referring to FIGS. 6 and 7, in at least a portion of the binding area BB, along the first direction DH, the first pads PA and the second pads PB are alternately arranged in sequence. In this way, the second pads PB can fully utilize spaces provided by the first connection portions PAY with a reduced size, and increase a width of the second pad PB.

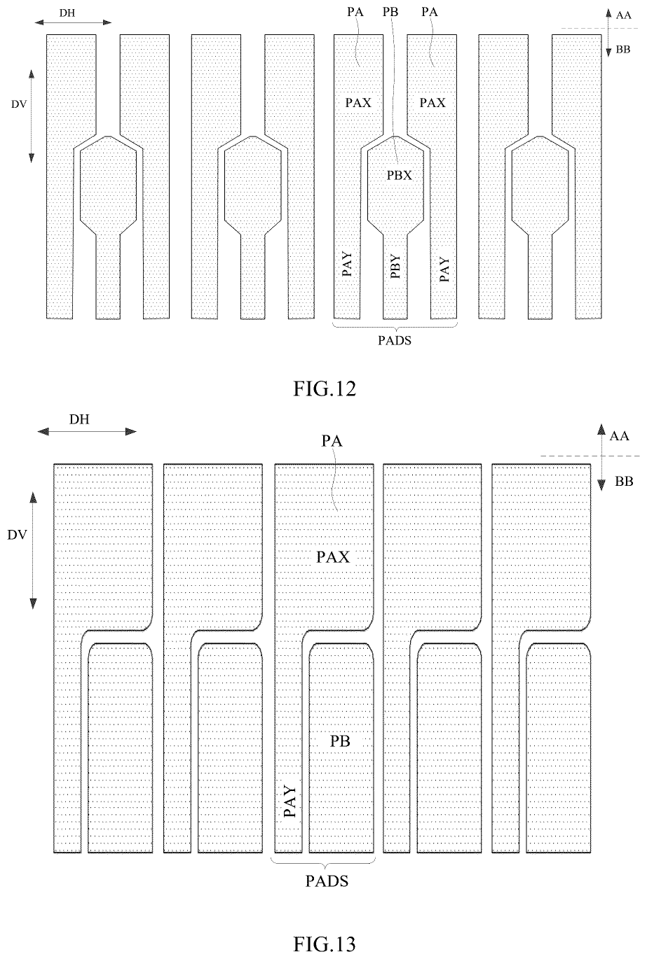

It can be understood that in other embodiments of the present disclosure, in at least a portion of the binding area BB, the first pads PA and the second pads PB may not be alternately arranged in sequence. For example, one or more second pads PB may be arranged for every multiple first pads PA, or one or more first pads PA may be arranged for every multiple second pads PB. For example, in the examples of FIGS. 11 and 12, one second pad PB is arranged every two first pads PA.

It can be understood that when multiple first pads PA are sequentially adjacent or multiple second pads PB are sequentially adjacent, the two first pads PA or two second pads PB that are sequentially adjacent may have the same or different shapes. For example, in the example of FIG. 11, two first pads PA are arranged adjacent to each other in sequence, and the shapes of the two first pads PA are different and asymmetric. In the example of FIG. 12, two first pads PA are arranged adjacent to each other in sequence, and the adjacent two first pads PA are symmetrically provided.

In one embodiment of the present disclosure, referring to FIGS. 6-7, the second pad PB includes a second connection portion PBY and a second structure PBX located on a side of the second connection portion PBY near the display area AA. A width L4 of the second structure PBX is greater than a width L5 of the second connection portion PBY. In this embodiment, the second pad PB is also designed with an irregular shape to ensure that a size of the second structure PBX is large enough for wire bonding process.

In one example, referring to FIGS. 6-7, each of the first connection portions PAY includes a first sub connection portion PAY1 electrically connected to a corresponding first structure PAX and a second sub connection portion PAY2 located on a side of the first sub connection portion PAY1 away from a corresponding first structure PAX. The width L2 of the first sub connection portion PAY1 is smaller than the width L3 of the second sub connection portion PAY2. The first sub connection portion PAY1 is located between adjacent second structures PBX. Furthermore, the second sub connection portion PAY2 is located between adjacent second connection portions PBY. In this example, a size of a portion (the first sub connection portion PAY1) of each of the first connection portions PAY adjacent to the second structure PBX may be further reduced to further increase layout space for the second structure PBX, further reducing squeezing of wiring space of the second structure PBX by the first pads PA, and enable the second structure PBX to have a sufficient width. After the first connection portions PAY pass between the second structures PBX, a size of a portion (i.e., the second sub connection portion PAY2) of the first connection portion PAY that is not adjacent to the second structure PBX increases to ensure a total layout area of the first pads PA and reduce their own impedance of the first pads PA. In this way, when the flexible circuit board is bound with conductive adhesive, both the first pads PA and the second pads PB have a larger effective binding area to avoid excessive binding impedance. When setting the metal wire WP through the wire bonding process, both the second structure PBX and the first structure PAX have sufficient widths to set the metal wire WP. Furthermore, a width L6 of a gap between a first sub connection portion PAY1 and an adjacent second structure PBX is smaller than a width L7 of a gap between a second sub connection portion PAY2 and an adjacent second connection portion PBY.

Of course, it can be understood that in other embodiments of the present disclosure, the width of the first sub connection portion PAY1 and the width of the second sub connection portion PAY2 may also be equal.

In one example, referring to FIGS. 6-7, the width L2 of the first sub connection portion PAY1 may not be less than 70 microns to ensure effective and low impedance electrical connection between the first structure PAX and the second sub connection portion PAY2. In addition, the first sub connection portion PAY1 has the width of not less than 70 microns, which can be effectively bound with the conductive adhesive and provide effective binding area in the conductive adhesive binding process, reducing binding impedance. For example, the width of the first sub connection portion PAY1 may be between 70-80 microns. This size design may not only provide lower impedance between the second sub connection portion PAY2 and the first structure PAX, but also provide an effective binding area of the first sub connection portion PAY1 during conductive adhesive binding. It can also avoid the first sub connection portion PAY1 being too large and squeezing the second structure PBX, allowing the second structure PBX to have the widest possible width.

In one example, referring to FIGS. 6 and 7, among the gaps between a second structure PBX and a first pad PA, the width L6 of the gap between the second structure PBX and the first sub connection portion PAY1 is the smallest. In this way, it is possible to minimize the squeezing of the second structure PBX by the first sub connection portion PAY1 and the gaps at its two sides (both sides along the first direction DH), so that the second structure PBX may have the widest possible width. Of course, it can be understood that other gaps between the second structure PBX and the first pad PA can be minimized as much as possible while meeting the requirements, in order to increase a total area of the first pads PA and/or the second pads PB, and thereby increase the effective binding area and reduce the binding impedance in the conductive adhesive binding process.

In one example, referring to FIGS. 6 and 7, the width L6 of the gap between the second structure PBX and the first sub connection portion PAY1 is not less than 35 microns, especially may be no less than 50 microns, to ensure sufficient insulation and reduce signal crosstalk between the second structure PBX and the first sub connection portion PAY1. For example, the width of the gap between the second structure PBX and the first sub connection portion PAY1 is between 50-60 microns. This size design can not only provide sufficient distance between the first sub connection portion PAY1 and the second structure PBX to achieve insulation and reduce crosstalk, but also avoid the gap being too wide and squeezing the second structure PBX, allowing the second structure PBX to have the widest possible width.

In one example, referring to FIGS. 6-7, the width L3 of the second sub connection portion PAY2 is 0.8 to 1.2 times the width L5 of the second connection portion PBY, especially their widths may be almost equal. In this way, the uniformity of the electrical characteristics of the first pads PA and the second pads PB may be improved. For example, the width of the second sub connection portion PAY2 and the width of the second connection portion PBY may both be in the range of 80-120 microns, such as 95-105 microns.

In one example, referring to FIGS. 6 and 7, the width L7 of the gap between the second sub connection portion PAY2 and the second connection portion PBY may be between 80 and 120 microns. For example, the width L7 of the gap between the second sub connection portion PAY2 and the second connection portion PBY may be between 95 and 105 microns.

In one example, referring to FIGS. 6-7, the width of the first structure PAX is 0.8 to 1.2 times the width of the second structure PBX, and in particular, the widths of the two may be almost equal. In this way, the uniformity of the electrical characteristics of the first pads PA and the second pads PB can be improved.

In one example, referring to FIGS. 6 and 7, the first structures PAX are arranged in a row along the first direction DH, and the second structures PBX are arranged in another row along the first direction DH. In this way, it is beneficial for the first structures PAX and the second structures PBX to perform wire bonding operation.

Alternatively, a shape of each of the first structures includes at least one of a right angled polygon and a rounded polygon. In the embodiments of the present disclosure, the right angled polygon refers to a polygon whose vertex is not chamfered or rounded, and it is not limited to the two sides that form the vertex being perpendicular to each other.

Alternatively, each of the first structures comprises a first transition structure connected to the first connection portion, and a first main body structure located on a side of the first transition structure away from the first connection portion. A width of the first transition structure gradually decreases along a direction away from the display area.

In one example, referring to FIGS. 6-7, each of the first structures PAX is generally pentagonal, and may include a rectangular first main body structure PAXM and a trapezoidal first transition structure PAXT. Wherein, a large end of the first transition structure PAXT (the lower bottom of the trapezoid) is connected to the first main body structure PAXM, and a small end of the first transition structure PAXT (the upper bottom of the trapezoid) is connected to the first connection portion PAY to achieve the size transition between the first main body structure PAXM and the first connection portion PAY. Of course, in other embodiments of the present disclosure, each of the first structures PAX may not be provided with the first transition structure PAXT, but instead allow the first main body structure PAXM to be directly connected to the first connection portion PAY. For example, in the example of FIG. 13, the first structure PAX does not have a trapezoidal first transition structure PAXT, but rather a rectangular first main body structure PAXM directly connected to the first connection portion PAY.

Alternatively, there is a third transition structure PAYT between the first and second sub connection portions PAY1 and PAY2, and the third transition structure is respectively connected to the first and second sub connection portions. AA width of the third transition structure gradually increases along the direction away from the display area. In one example, referring to FIGS. 6 and 7, the trapezoidal third transition structure PAYT is provided at the junction of the first and second sub connection portions PAY1 and PAY2. Wherein, a small end of the third transition structure PAYT (an upper bottom of the trapezoid) is connected to the first sub connection portion PAY1, and a large end of the third transition structure PAYT (a lower bottom of the trapezoid) is connected to the second sub connection portion PAY2. In this way, a gradual transition can be achieved between the first sub connection portion PAY1 and the second sub connection portion PAY2. Of course, it can be understood that in other embodiments of the present disclosure, the first sub connection portion PAY1 and the second sub connection portion PAY2 may also be directly electrically connected.

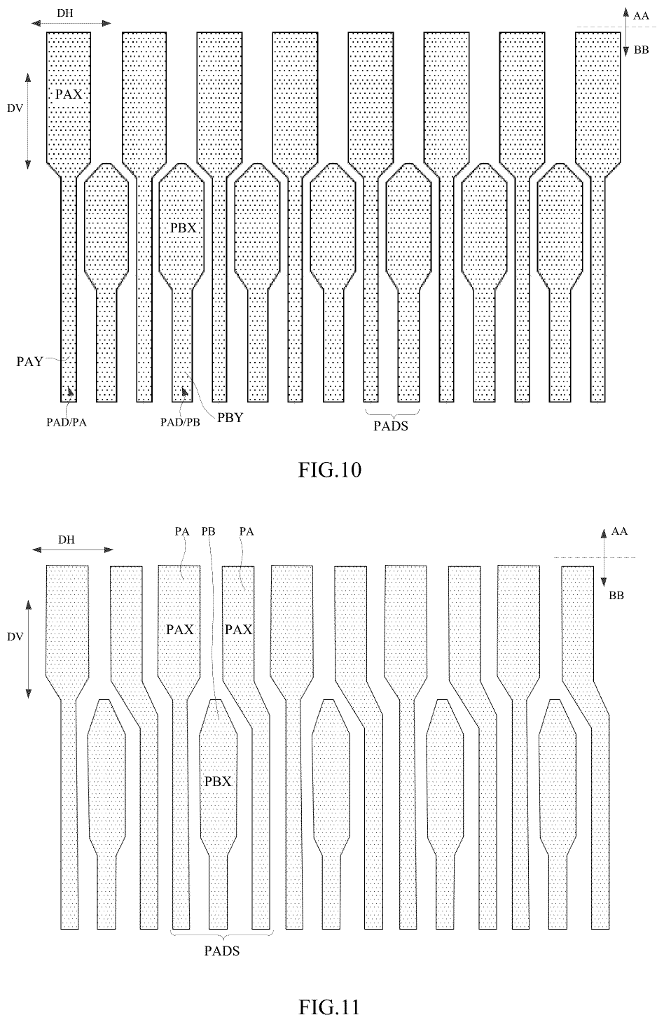

In the example of FIGS. 6 and 7, each of the first connection portions PAY is illustrated as including the first sub connection portion PAY1 and the second sub connection portion PAY2. It can be understood that in other examples of the present disclosure, the width of each of the first connection portions PAY may also be uniform rather than variable, for example, each of the first connection portions PAY may also be arranged in a relatively uniform strip shape without being locally narrowed. For example, in the example shown in FIG. 10, each of the first pads PA includes a first structure PAX and a first connection portion PAY, and each of the first connection portions PAY is arranged in a strip shape with equal width.

A shape of the second structure includes at least one of the right angled polygon and the rounded polygon, for example, it can include a rounded rectangle, pentagon, hexagon, heptagon, octagon, etc.

In one example, referring to FIGS. 6 and 7, each of the second structures PBX may have a rectangular second main body structure PBXM as a main portion of the wire bonding portion.

Alternatively, the second structure comprises a second main body structure and a protruding structure located on one side of the second main body structure near the display area. Furthermore, a width of the protruding structure gradually decreases along a direction near the display area.

In one example, the second structure PBX may further be provided with a protruding structure PBXG that protrudes towards one side of the second main body structure PBXM near the display area AA. At least a portion of the edge of the protruding structure PBXG may be parallel to an edge of an adjacent first structure PAX, so as to maximize an area of the protruding structure PBXG, which may increase a total area of the second pad PB. For example, in the example of FIGS. 6 and 7, the protruding structure PBXG is arranged in a trapezoidal shape, with a large end of the protruding structure PBXG (a lower bottom of the trapezoid) connected to the second main body structure PBXM, and a small end of the protruding structure PBXG (an upper bottom of the trapezoid) located near an end of the display area AA. A side of the protruding structure PBXG (a waist of the trapezoid) is adjacent to and parallel to a side of the first transition structure PAXT. Furthermore, the small end of the protruding structure PBXG does not extend between adjacent first main body structures PAXM to avoid occupying space of the first main body structure PAXM. For example, referring to FIG. 9, the protruding structure PBXG may form a triangle, with one side connected to the second main body structure PBXM, and the other two sides adjacent and parallel to the sides of two adjacent first transition structures PAXT. Furthermore, a top of the protruding structure PBXG (near a top corner of the display area AA) may not extend between adjacent first main body structures PAXM to avoid occupying the space of the first main body structure PAXM.

In the embodiments of the present disclosure, two parallel edges refer to that main body parts of the two edges are essentially parallel, such as middle parts of the two edges being essentially parallel. End portions of two parallel edges, which may or may not be parallel to each other. For example, when a top corner of the pad is rounded, end portions of the two parallel edges are not parallel to each other. Generally, due to factors such as process errors, an angle between two parallel edges does not necessarily have to be 0°, but may have deviations. In the present disclosure, when the angle between the main body parts of two edges is not greater than 10°, the two edges may be considered parallel.

Alternatively, the second structure comprises a second main body structure and a second transition structure located on a side of the second main body structure away from the display area. One end of the second transition structure is connected to the second connection portion, and the other end is connected to the second main body structure. A size of the second transition structure gradually decreases in the direction away from the display area.

In one example, referring to FIGS. 6 and 7, each of the second structures PBX may further include a second transition structure PBXT located between the second main body structure PBXM and the second connection portion PBY to achieve transition between the second main body structure PBXM and the second connection portion PBY. The second transition structure PBXT is trapezoidal, with its large end (a bottom of the trapezoid) connected to the second main body structure PBXM, and its small end (a top of the trapezoid) connected to the second connection portion PBY. Furthermore, a side of the second transition structure PBXT is not parallel to a side of an adjacent third transition structure PAYT, so that a width of a gap between the second transition structure PBXT and the adjacent third transition structure PAYT gradually increases in the direction away from the display area AA. Of course, in other embodiments of the present disclosure, a side of the second transition structure PBXT and a side of the adjacent third transition structure PAYT may be parallel to each other. Alternatively, as shown in FIG. 15, there is no second transition structure PBXT for size transition between the second main body structure PBXM and the second connection portion PBY.

Alternatively, a length of the wire bonding portion of the pad PAD (a size of the wire bonding portion along the second direction DV) may be no less than 200 microns to meet the size requirements of the wire bonding. Furthermore, the length of the wire bonding portion of the pad PAD should be no less than twice the width of the wire bonding portion of the pad PAD, for example, it may be 2-4 times the width of the wire bonding portion, in order to make the pad PAD have a larger area and reduce the binding impedance during conductive adhesive binding.

In one example, a length of a main body part of the wire bonding portion of the pad PAD (such as the first main body structure PAXM of the first structure PAX, and the second main body structure PBXM of the second structure PBX) may be 2-3 times its width. For example, a width of the first main body structure PAXM may be 2.3 to 2.7 times the width of the first structure PAX. For example, a width of the second main body structure PBXM may be 2.3 to 2.7 times the width of the second structure PBX.

In one example, referring to FIGS. 6 and 7, an extension line of a centerline of the second pad PB (along a centerline of the second direction DV) may be located in a gap between adjacent two first structures PAX. And/or, an extension line of a centerline of the first pad PA (along the centerline of the second direction DV) may be located in a gap between adjacent two second pads PB. In this way, along the first direction DH, the first structure PAX and the second pad PB are arranged alternately, which can reduce the interference between the metal wires WP and improve the wire bonding yield during wire bonding. It can be understood that in other embodiments of the present disclosure, such as the examples shown in FIGS. 13 to 15, the centerline of the second pad PB may also pass through an area where the first pad PA is located, or the centerline of the first pad PA may also pass through an area where the second pad PB is located. During wire bonding, the metal wires WP connected to the first pad PA and the metal wires WP connected to the second pad PB can be avoided from each other.

It can be understood that when the first pad PA is symmetrical, the centerline of the first pad PA along the second direction DV is an axis of symmetry of the first pad PA. When the second pad PB is symmetrical, the centerline of the second pad PB along the second direction DV is an axis of symmetry of the second pad PB.

In one example, referring to FIGS. 6 and 7, the first pad PA is axisymmetric along its centerline (the centerline along the second direction DV). In this way, there is an accommodating space between two adjacent first connection portions PAY for arranging the second pad PB, and a centerline of the accommodating space (the centerline along the second direction DV) passes through the gap between two adjacent first structures PAX. Furthermore, referring to FIGS. 6 and 7, the second pad PB is symmetrical along its centerline (the centerline along the second direction DV), and its centerline coincides with the centerline of the accommodating space. Thus, the adjacent three pads PAD form a symmetrical structure. For example, three adjacent pads PAD, namely the first pad PA, the second pad PB, and the first pad PA, are symmetrical about the centerline of the second pad PB (the centerline along the second direction DV). For example, three adjacent pads PAD, namely the second pad PB, the first pad PA, and the second pad PB, are symmetrical about the centerline of the first pad PA (the centerline along the second direction DV).

It can be understood that in other embodiments of the present disclosure, at least one of the first pad PA and the second pad PB may be asymmetrically provided.

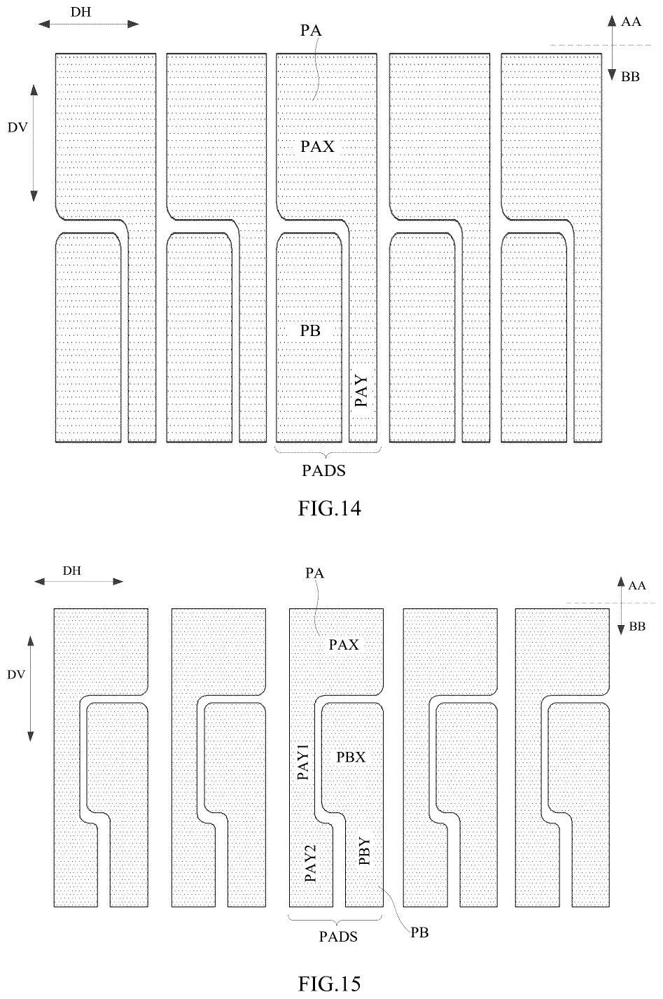

For example, in the examples of FIGS. 13 and 14, along the first direction DH, the first connection portion PAY is located on one side of the first pad PA; the first pad PA and the second pad PB form a pad group PADS. In the same pad group PADS, the second pad PB is located in a gap defined by the first structure PAX and the first connection portion PAY; along the first direction DH, the second pad PB does not protrude from the first structure PAX. In this example, the first pad PA includes a first structure PAX and a first connection portion PAY; wherein, the centerline of the first structure PAX (the centerline along the second direction DV) and the centerline of the first connection portion PAY (the centerline along the second direction DV) do not coincide, which makes the first pad PA not a symmetrical structure. Furthermore, both the first structure PAX and the first connection portion PAY are rectangular in shape.

In this example, alternatively, referring to FIGS. 13 and 14, an extension direction of one edge of the first structure PAX along the second direction DV coincides with an extension direction of one edge of the first connection portion PAY along the second direction DV. This creates a gap between the first structure PAX and the first connection portion PAY to accommodate the second pad PB, which does not protrude from the first structure PAX in the first direction DH. Furthermore, the second pad PB can be rectangular in shape and have a symmetrical structure.

For example, in the example of FIG. 15, the first pad PA includes the first structure PAX and the first connection portion PAY. Wherein, the first connection portion PAY includes the first sub connection portion PAY1 and the second sub connection portion PAY2. Wherein, a centerline of the first sub connection portion PAY1 (the centerline along the second direction DV), a centerline of the second sub connection portion PAY2 (the centerline along the second direction DV), and a centerline of the first structure PAX (the centerline along the second direction DV) do not coincide. This makes the first pad PA not a symmetrical structure. Furthermore, the first structure PAX, the first sub connection portion PAY1, and the second sub connection portion PAY2 are all rectangular in shape.

In this example, alternatively, as shown in FIG. 15, an extension direction of one edge of the first structure PAX along the second direction DV coincides with an extension direction of one edge of the first sub connection portion PAYI along the second direction DV, and an extension direction of one edge of the second sub connection portion PAY2 along the second direction DV. This creates a gap between the first structure PAX and the first connection portion PAY to accommodate the second pad PB, which does not protrude from the first structure PAX in the first direction DH. Furthermore, the second pad PB may include the second structural PBX adjacent to the first sub connection portion PAY1 and a second connection portion PBY adjacent to the second sub connection portion PAY2, and an extension direction of one of the edges of the second structural PBX along the second direction DV coincides with an extension direction of one of the edges of the second connection portion PBY along the second direction DV. So, the second pad PB is not a symmetrical structure.

In one embodiment of the present disclosure, referring to FIG. 8, the pad PAD may further include the third pad PC located at an end of the pad PAD row. Due to the fact that only one side of the third pad PC is adjacent to the other pad PAD, it experiences less spatial squeezing. Therefore, it may be designed without using irregular shape, or may be deformed according to the pattern of the first pad PA or the second pad PB. It may also be independently deformed to have a different shape from the first pad PA and the second pad PB. In the example of FIG. 8, a shape of the third pad PC is different from that of the first pad PA and the second pad PB, and it includes a third structure PCX and a third connection portion PCY located on a side of the third structure PCX away from the display area AA. Wherein, a width of the third structure PCX may be greater than a width of the third connection portion PCY, so that the third structure PCX has sufficient width for wire bonding. In one example, multiple first pads and multiple second pads form a first pad area, wherein the third pads are located on both sides of the first pad area, along a direction facing the first pad area (first direction DH), the width of the third structure PCX is greater than or equal to the width of the third connection portion PCY. Furthermore, the third structure PCX is arranged in the same row as the first structure PAX. A total side of the third structure PCX adjacent to the second pad PB (i.e., the edges of the third pad PC adjacent to the first pad area) may be the same as one total side of the first structure PAX. In the embodiments of the present disclosure, the total side of the pad PAD refers to the collection of edges located on one side of the pad PAD in the first direction DH, which may reflect the contour of the pad PAD on one side of the first direction DH. In this way, the electrical environment of the second pad PB adjacent to the third pad PC may be made the same as that of the other second pads PB.

In one embodiment of the present disclosure, adjacent multiple pads PAD may form the pad group PADS; in at least a portion of the binding area BB, multiple pad groups PADS may be sequentially adjacent and arranged along the first direction DH. In this way, in the binding area BB, each pad PAD is arranged periodically in a local area or the entire area. It can be understood that there may be some pads PAD in the binding area BB that do not belong to the pad group PADS, for example, one or more pads PAD near the end may not belong to any pad group PADS. Of course, it is also possible to assign each pad PAD to one pad group PADS. It can be understood that according to different classification rules, the pad group PADS may include pads PAD of different quantities, shapes, and positions.

In one example, referring to FIG. 6, the pad group PADS may include two pads PAD, namely one first pad PA and one second pad PB. In this example, in the same pad group PADS, the centerline of the first pad PA (the centerline along the second direction DV) does not pass through the second pad PB, and the centerline of the second pad PB (the centerline along the second direction DV) does not pass through the first pad PA. In this way, it is advantageous for the metal wire WP connected to the first pad PA and the metal wire WP connected to the second pad PB to avoid each other during wire bonding.

In another example, referring to FIGS. 13-15, the pad group PADS may include two pads PAD, namely one first pad PA and one second pad PB. In this example, in the same pad group PADS, the centerline of the first pad PA (the centerline along the second direction DV) passes through the second pad PB, and the centerline of the second pad PB (the centerline along the second direction DV) passes through the first pad PA. In this example, the centerline of the first pad PA and the centerline of the second pad PB do not coincide, so the metal wire WP connected to the first pad PA and the metal wire WP connected to the second pad PB may also avoid each other.

In another example, referring to FIGS. 11 and 12, the pad group PADS may include three pads PAD, namely two first pads PA and one second pad PB located between the two first pads PA. It can be understood, however, in other embodiments of the present disclosure, the pad group PADS may also include two second pads PB and one first pad PA located between the two second pads PB.

In one example, the same pad group PADS may be symmetrically provided as a whole. For example, in the example of FIG. 12, the two first pads PA of the pad group PADS may be symmetrically provided about the centerline of the second pad PB. Furthermore, in this example, the first pad PA itself may not be symmetrically provided, for example, the first connection portion PAY of the first pad PA is located on the side of the first pad PA away from the second pad PB, rather than in the middle of the first pad PA.

In another example, the same pad group PADS may not be symmetrically provided as a whole. For example, when the pad group PADS includes two pads PAD, the overall pattern of the pad group PADS is not symmetrically provided. For example, in the example shown in FIG. 11, the pad group PADS includes three pads PAD, but the overall pattern of the pad group PADS is not symmetrically provided.

In one example, the pad group PADS includes the first pad PA and the second pad PB; wherein, referring to FIGS. 6 and 7, in the orthographic projection of the first pad PA and the second pad PB on the adjacent edge of the display panel PNL, the orthographic projection of the first pad PA partially overlaps with the orthographic projection of the second pad PB. Thus, overall, the first pad PA and the second pad PB are arranged in a staggered manner.

In another example, the pad group PADS includes the first pad PA and the second pad PB; wherein, referring to FIGS. 13 and 14, in the orthographic projection of the first pad PA and the second pad PB on the adjacent edge of the display panel PNL, the orthographic projection of the second pad PB is completely located within the orthographic projection of the first pad PA. Specifically, along the first direction DH, the first connection portion PAY is located on one side of the first pad PA. In the same pad group PADS, the second pad PB is located in the gap defined by the first structure PAX and the first connection portion PAY, along the first direction DH, the second pad PB does not protrude from the first structure PAX.

In the display panel PNL provided in the embodiment of the present disclosure, the pads PAD in the binding area BB are arranged in a row along the first direction DH, and at least include the first pad PA and the second pad PB; wherein, the wire bonding portion of the first pad PA and the wire bonding portion of the second pad PB are not located on the same straight line and are offset in the second direction DV. In other words, the wire bonding portions of the first pad PA (such as the first structure PAX) are arranged in a row, and the wire bonding portions of the second pad PB (such as the second pad PB itself or the second structure PBX) are arranged in another row. In the examples of FIGS. 6 to 15, the arrangement of the wire bonding portion of the pad PAD in two rows is taken as an example for illustrative explanation. It can be understood that in other embodiments of the present disclosure, the wire bonding portion of the pad PAD in the binding area BB (the portion of the pad PAD with the largest size along the first direction DH) may also be arranged in three rows or more to further reduce the squeezing between adjacent pads PAD and increase the size of the wire bonding portion of the pad PAD in the first direction DH.

Alternatively, at least one top corner of the pad is an arc-shaped or obtuse corner, for example, at least one top corner is a rounded corner. For example, the top corners of the pad PAD may be obtuse or rounded, for example, any top corner of the pad PAD may be an obtuse angle of 110-150°, in order to reduce the risk of scratching the film layer at the top corner of the pad PAD and reduce the risk of tip discharge. In one example, when the top corner of the pad PAD is adjacent to the other pad PAD, the top corner is rounded.

After considering the specification and practicing the invention disclosed herein, those skilled in the art would easily come up with other implementation solutions of the present disclosure. The present application aims to cover any variations, usages, or adaptive changes of the present disclosure, which follow the general principles of the present disclosure and include common knowledge or customary technical means in the art not disclosed in the present disclosure. The specification and embodiments are only considered exemplary.

1. A display panel, wherein the display panel comprises a display area and a binding area located on one side of the display area; wherein, in the binding area, there are multiple pads arranged in sequence along a first direction;
wherein, the multiple pads at least comprise multiple first pads and multiple second pads; each of the first pads comprises a first structure and a first connection portion located on one side of the first structure away from the display area, a maximum width of the first structure is greater than a maximum width of the first connection portion;
the first structure is located on one side of a corresponding second pad near the display area.

2. The display panel according to claim 1, wherein each of the second pads comprises a second connection portion and a second structure located on one side of the second connection portion near the display area, and a maximum width of the second structure is greater than a maximum width of the second connection portion.

3. The display panel according to claim 2, wherein the first connection portion comprises a first sub connection portion electrically connected to the first structure and a second sub connection portion located on one side of the first sub connection portion away from the first structure;
a width of the first sub connection portion is less than or equal to a width of the second sub connection portion.

4. The display panel according to claim 3, wherein the first sub connection portion is located between adjacent second structures; the second sub connection portion is located between adjacent second connection portions.

5. The display panel according to claim 3, wherein the width of the second sub connection portion is 0.8 to 1.2 times a width of the second connection portion.

6. The display panel according to claim 3, wherein a third transition structure is included between the first sub connection portion and the second sub connection portion; the third transition structure is respectively connected to the first sub connection portion and the second sub connection portion; a width of the third transition structure gradually increases along a direction away from the display area.

7. The display panel according to claim 2, wherein a shape of the first structure comprises at least one of a right angled polygon and a rounded polygon;
the first structure comprises a first transition structure connected to the first connection portion, and a first main body structure located on a side of the first transition structure away from the first connection portion;
a width of the first transition structure gradually decreases along a direction away from the display area.

8. The display panel according to claim 7, wherein the shape of the second structure comprises at least one of a right angled polygon and a rounded polygon;
the second structure comprises a second main body structure and a protruding structure located on one side of the second main body structure near the display area, and at least a portion of an edge of the protruding structure is parallel to an edge of an adjacent one of the first structures.

9. The display panel according to claim 8, wherein the protruding structure is trapezoidal;
a width of the protruding structure gradually decreases along a direction near the display area; a side of the protruding structure is parallel to a side of an adjacent one of the first transition structures.

10. The display panel according to claim 7, wherein a shape of the second structure comprises at least one of a right angled polygon and a rounded polygon;
the second structure has a second main body structure and a second transition structure located on one side of the second main body structure away from the display area;
one end of the second transition structure is connected to the second connection portion, and the other end of the second transition structure is connected to the second main body structure; a size of the second transition structure gradually decreases in the direction away from the display area.

11. The display panel according to claim 2, wherein a width of the first structure is 0.8 to 1.2 times a width of the second structure.

12. The display panel according to claim 2, wherein the first structures are arranged in a row along the first direction, and the second structures are arranged in another row along the first direction.

13. The display panel according to claim 3, wherein a width of a gap between the first sub connection portion and the second structure is smaller than a width of a gap between the second sub connection portion and the second connection portion.

14. The display panel according to claim 1, wherein the first connection portion is located on one side of a corresponding first pad along the first direction, and one first pad and one second pad form a pad group;
in a same pad group, the second pad is located in a gap defined by the first structure and the first connection portion, and the second pad does not protrude from the first structure along the first direction.

15. The display panel according to claim 1, wherein the first pads are arranged axially symmetrically, and an extension line of a symmetry axis of the first pads is located in a gap between two adjacent second pads;
and/or, the second pads are arranged axially symmetrically, and an extension line of a symmetry axis of the second pads is located in a gap between two adjacent first structures.

16. The display panel according to claim 1, wherein in at least a portion of the binding area, the first pads and the second pads are alternately arranged in sequence along the first direction, and the first connection portion passes through the gap between adjacent second pads.

17. The display panel according to claim 1, wherein the multiple pads comprise third pads, the multiple first pads and the multiple second pads form a first pad area, and the third pads are respectively located on both sides of the first pad area;
wherein, each of the third pads comprises a third structure and a third connection portion, and a width of the third structure is greater than or equal to a width of the third connection portion along a direction facing the first pad area.

18. The display panel according to claim 1, wherein at least one top corner of each of the pads is an arc-shaped corner.

19. The display panel according to claim 1, wherein the maximum width of the first structure and a maximum width of the second pad are both not less than 200 microns.

20. A display device comprising the display panel according to claim 1.
